(19) United States
(12) Patent Application Publication
(10) Pub. No.: US 2026/0052983 A1
(43) Pub. Date: Feb. 19, 2026

(54) HEAT DISSIPATION STRUCTURE FOR INTEGRATED CIRCUIT PACKAGES

(71) Applicant: Taiwan Semiconductor Manufacturing Company, Ltd., Hsinchu (TW)

(72) Inventors: Chien-Chang Wang, Hsinchu City (TW); Bang-Li Wu, Hsinchu City (TW); Ching Wang, Taichung City (TW); Kuo-Chin Chang, Chiayi City (TW); Kathy Wei Yan, Hsinchu (TW)

(21) Appl. No.: 18/934,389

(22) Filed: Nov. 1, 2024

Related U.S. Application Data
(60) Provisional application No. 63/684,654, filed on Aug. 19, 2024.

(51) Int. Cl. H01L 23/367; H01L 23/00; H01L 23/10; H01L 23/373; H01L 23/538; H01L 25/065; H10B 80/00

(52) U.S. Cl. CPC H01L 23/3675; H01L 23/10; H01L 23/3736; H01L 24/29; H01L 24/32; H01L 25/0655; H01L 23/5385; H01L 2224/29105; H01L 2224/29118; H01L 2224/29124; H01L 2224/32245; H10B 80/00

(57) ABSTRACT

A package substrate according to the present disclosure includes a package substrate, a package component bonded to the package substrate and including a plurality of dies, a lid disposed over the package component and the package substrate, and a thermal interface material (TIM) layer sandwiched between the package component and the lid. The lid includes a plurality of heat spreader patterns that extend from a bottom surface of the lid into the TIM layer.

### PRIORITY DATA

This application claims the benefit of U.S. Provisional Application No. 63/684,654, filed Aug. 19, 2024, which is hereby incorporated by reference in its entirety.

### BACKGROUND

In some Three-Dimensional Integrated Circuits (3DIC), device dies are bonded to a package substrate to form a package. The heat generated by the device dies during operation needs to be dissipated to prevent performance degradation or even physical damage. To dissipate heat, a metal lid may be bonded the package substrates to engage the device dies. Device dies may experience warpage due to temperature variation. Warpage may put a strain on the adhesion between the devices and the metal lid.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a package structure, according to various aspects of the present disclosure.

FIGS. 2-14 illustrate fragmentary cross-sectional views or top views of a work-in-progress (WIP) structure going through various steps of the method in FIG. 1, according to various aspects of the present disclosure.

FIGS. 15-19 illustrate different protruding pattern arrangements according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Semiconductor packaging technologies were once just considered backend processes that facilitate chips to interface external circuitry. It is no longer the case. Computing workloads have evolved so much that brought packaging technologies to the forefront of innovation. Modern packaging provides integration of multiple chips or dies into a single semiconductor device. Depending on the level of stacking, modern semiconductor packages can have a 2.5D structure or a 3D structure. In a 2.5D structure, at least two dies are coupled to a redistribution layer (RDL) structure or an interposer that provides chip-to-chip communication. The at least two dies in a 2.5D structure are not stacked one over another vertically and the RDL structure or the interposer is bonded to a package substrate. In a 3D structure, at least two dies are stacked one over another and interact with each other by way of through silicon vias (TSVs). Depending on the processes adopted, the 2.5D structure and the 3D structure may have an Integrated Fan-Out (InFO) construction or a Chip-on-Wafer-on-Substrate (CoWoS®) construction. To provide additional structural integrity and to improve heat dissipation, a metal lid may be attached to the package structure. Because a coefficient of thermal expansion of the package substrate is much greater than a coefficient of thermal expansion of the metal lid, the metal lid and the package substrate may warp differently during heat cycles. This warpage difference puts a strain on the adhesion interface between the package structure and the metal lid. For example, a thermal interface material (TIM) may be present at the interface. When the adhesion fails, the TIM may suffer coverage loss, thereby interrupting the heat dissipation and degrading thermal performance. This kind of failure may become more likely when the semiconductor package undergoes environmental testing, such as moisture sensitivity level testing.

The present disclosure provides a package structure where a warpage difference between the metal lid and the package substrate is reduced or minimized. In some examples, a heat spreader of the metal lid that interfaces the dies includes fractured protruding patterns. The fractured protruding patterns provide more flexibility to the metal lid. In some examples, a metal frame is formed on the package substrate to surround the dies. The metal frame may include a plurality of guide pins that partially extend into the package substrate and functions to provide more rigidity to the package substrate. In some other examples, a package structure according to the present disclosure includes both fractured protruding patterns and a metal frame to further control the warpage difference between the metal lid and the package substrate.

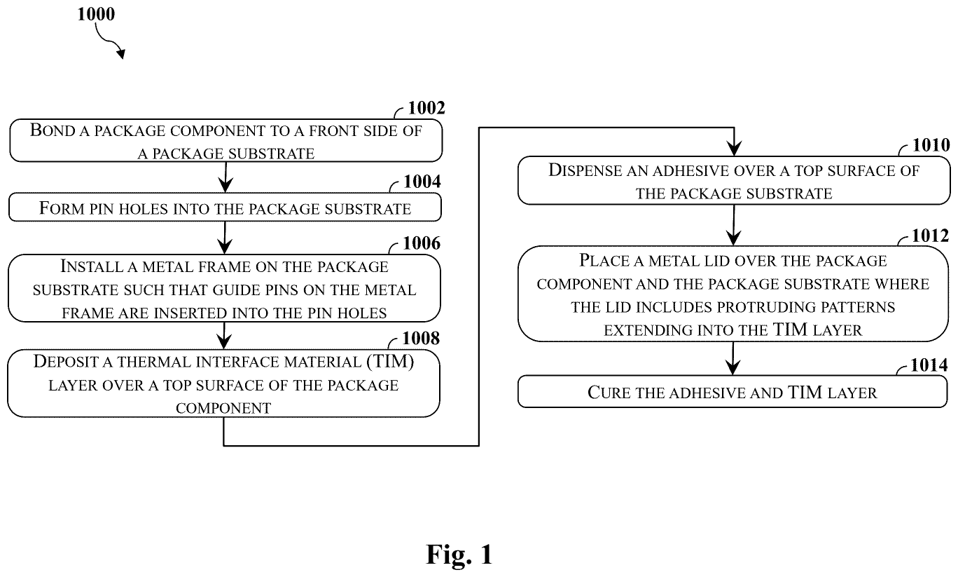

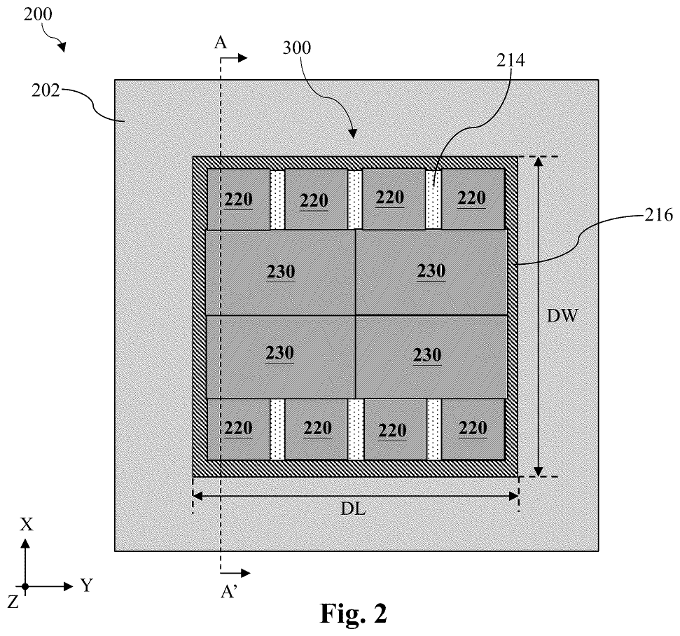

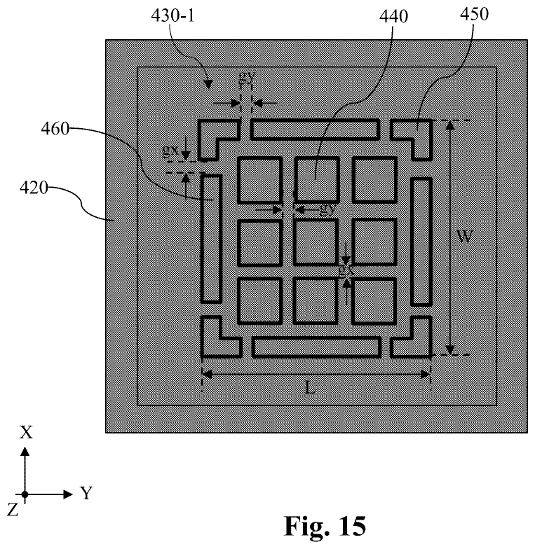

The various aspects of the present disclosure will now be described in more detail with reference to the figures. In that regard, FIG. 1 is a flowchart illustrating method 1000 of forming a package structure on a work-in-progress (WIP) structure 200 (shown in FIGS. 2-14), according to various aspects of the present disclosure. Method 1000 is merely an example and is not intended to limit the present disclosure to what is explicitly illustrated in method 1000. Additional steps can be provided before, during and after method 1000, and some steps described can be replaced, eliminated, or moved around for additional embodiments of the method. Not all steps are described herein in detail for reasons of simplicity. Method 1000 is described below in conjunction with FIG. 2-14, which are fragmentary cross-sectional views and top views of the WIP structure 200 at different stages of fabrication according to various embodiments of method 1000. Because the WIP structure 200 will be fabricated into a package structure, the WIP structure 200 may be referred to herein as a package structure 200 as the context requires. For avoidance of doubts, the X, Y and Z directions in FIGS. 2-14 as well as FIGS. 15-19 are perpendicular to one another. Throughout the present disclosure, unless expressly otherwise described, like reference numerals denote like features.

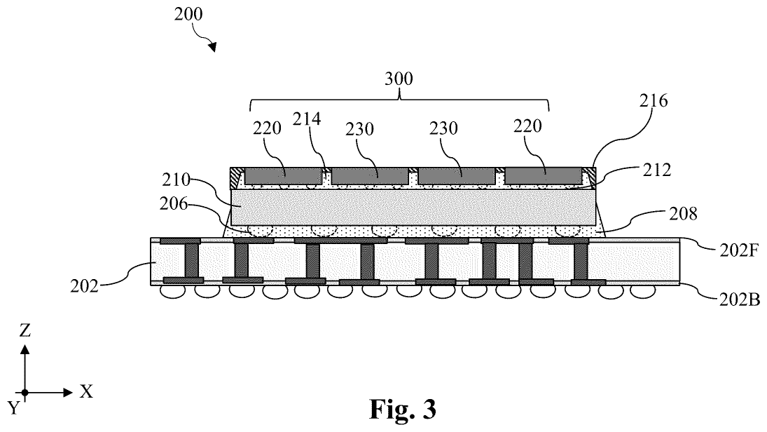

Referring to FIGS. 1, 2 and 3, method 1000 includes a block 1002 where a package component 300 is bonded to a frontside surface 202F of a package substrate 202. FIG. 2 illustrates a schematic top view of the package component 300 over the package substrate 202. FIG. 3 illustrates a cross-sectional view along cross-section A-A′ in FIG. 2. In some embodiments, the package substrate 202 may include a printed circuit board (PCB) or the like, which may include fiberglass reinforced epoxy resin (FR-4), Polytetrafluoroethylene (PTFE), and metal traces. Reference is made to FIG. 3. In order to electrically couple to the package component 300, the package substrate 202 may include a plurality of contact pads over the frontside surface 202F. To electrically couple to solder features over the backside surface 202B, the package substrate 202 may also include a plurality of contact pads over the backside surface 202B. The package component 300 is a multi-die package (or multi-chip package) that may include more than one device die. A device die may also be referred to as a die or a chip. In the depicted embodiment shown in FIGS. 2 and 3, the package component 300 includes multiple high-bandwidth-memory (HBM) dies 220 and multiple system-on-chip (SoC) dies 230. In some other embodiments, the package component 300 may include, alternatively or additionally, logic dies or application specific integrated circuit (ASIC) dies. In some instances, each of the SoC dies 230 is connected to two HBM dies 220. In some embodiments represented in FIG. 2, each of HBM dies 220 and the SoC dies 230 is bonded to the interposer 210 by way of a plurality of micro-bumps 212. The space between the interposer 210 and each of the HBM dies 220 and the SoC dies 230 may be filled with a first underfill 214. The HBM dies 220 and the SoC dies 230 are disposed side-by-side over the interposer 210. To provide structural integrity and to improve stress absorption, upper edges of the package component 300 are surrounded by a molding compound 216. Spaces among the HBM dies 220 and the SoC dies 230 may be filled by the first underfill 214. The molding compound 216 may also be referred to as an encapsulation layer 216. The package component 300 further includes a plurality of connection features 206 to interface the package substrate 202. In some embodiments, the plurality of connection features 206 may include controlled collapse chip connection (C4) bumps or other solder bumps. As illustrated in FIG. 3, the space between the package component 300 and the frontside surface 202F of the package substrate 202 may be filled with a second underfill 208. In some embodiments represented in FIG. 2, the second underfill 208 may wrap around sidewalls of the interposer 210.

HBM is a computer memory interface that is commonly used in conjunction with high-performance graphics accelerators, high-performance data center, ASIC for AI application, on-package cache in CPUs, or high-performance computing ICs. An HBM die 220 may include a vertical stack of dynamic random access memory (DRAM) dies. In some instances, an HBM die may include 2 to 10 DRAM dies stacked together. The vertical stacking allows for higher bandwidth, smaller power consumption, and smaller form factor. HBM has been accepted as an industry standard. So far there have been three generations—HBM1, HBM2 and HBM3. The fourth generation—HBM4 is set to be released by the end of 2024. The HBM dies 220 include HBM dies with all current and future generations of HBM standards. An SoC die 230 may include a memory controller than interfaces the HBM dies 220 and a graphic processing unit (GPU), a central processing unit (CPU), or a neural processing unit (NPU). The memory controller is normally built-in in the SoC die 230 and that is why the SoC die 230 is referred to as “System-on-Chip.”

The interposer 210 may include a semiconductor material or glass. In one embodiment, the interposer 210 includes silicon (Si). In some alternative embodiments, the interposer 210 includes silicon germanium (SiGe) or silicon carbon (SIC). Each of the HBM dies 220 and the SoC dies 230 may include a plurality of transistors, such as planar transistors, fin-type field effect transistors (FinFETs), gate-all-around (GAA) transistors, nanowire transistors, nanosheet transistors, or other multi-gate transistors. The first underfill 214 and the second underfill 208 may include polymer or epoxy. The molding compound 216 may include a base material and fillers embedded in the base material. In some implementations, the base material of the molding compound 216 may include polymer, resin or epoxy and the fillers may include spherical particles of silicon oxide (silica) or aluminum oxide.

Reference is made to FIG. 2, which provides a top view of the package component 300. In some embodiments represented in FIG. 2, spaces among the HBM dies 220 and the SoC dies 230 may be filled with the first underfill 214 and an upper portion of the package component 300 may be surrounded by the molding compound 216. Each of the HBM dies 220 and the SoC dies 230 may have a flip chip configuration with their back sides of their device substrates or carrier substrates exposed on the top surface of the package component 300. In some implementations, the device substrates or carrier substrates may include silicon (Si). As a result, different materials may be exposed on a top surface of the package component 300. The molding compound 216 exposed on the top surface of the package component 300 may include polymer, resin, epoxy, silicon oxide (silica), aluminum oxide, or a combination thereof. The first underfill 214 exposed on the top surface of the package component 300 may include polymer or epoxy. The package component 300 includes a die width (DW) along the X direction and a die length (DL) along the Y direction.

At block 1002, the package component 300 is placed over the package substrate 202 such that the connection features 206 are vertically aligned with the contact pads on the frontside surface 202F of the package substrate 202. A reflow process is performed such that the connection features 206 electrically couple the interposer 210 of the package component 300 to the package substrate 202. After the reflow process, a liquid precursor of the second underfill 208 is allowed to fill the gap between the interposer 210 and the frontside surface 202F of the package substrate 202 through capillary action. The package substrate 202 and the package component 300 shown in FIGS. 2 and 3 may be collectively referred to as a work-in-progress (WIP) structure 200. During operations at various blocks of method 1000, components may be added to the WIP structure 200 and the present disclosure will continue to refer to the resulting structure as the WIP structure 200.

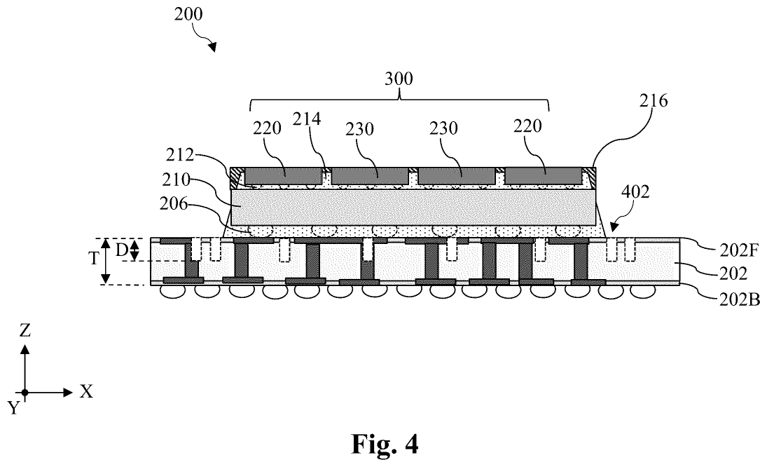

Referring to FIGS. 1 and 4-7, method 1000 includes a block 1004 where pin holes 402 are formed in the package substrate 202. In some embodiments, the pin holes 402 may be formed using laser drilling. As shown in FIG. 4, each of the pin holes 402 may extend a depth D into the package substrate 202 that has a thickness T. The thickness T of the package substrate 202 may be between 0.2 mm and about 3.2 mm. In some embodiments, a ratio of the depth D to the thickness T may be between about 0.1 and about 0.9. This range is not trivial. When the ratio is smaller than 0.1, the pin holes 402 would be too shallow to provide mechanical anchoring for the to-be-installed metal frame. When the ratio is greater than 0.9, the pin holes 402 may expose conductive features near the backside surface 202B of the package substrate 202, thereby increasing electrical shorts risks. It is noted that none of the pin holes 402 exposes any conductive features in the package substrate 202. Because pin holes 402 are to be inserted with guide pins of a metal frame that is formed of a conductive material, exposure of conductive features in the pin holes 402 may result in unintended electrical connections, which may cause device failure.

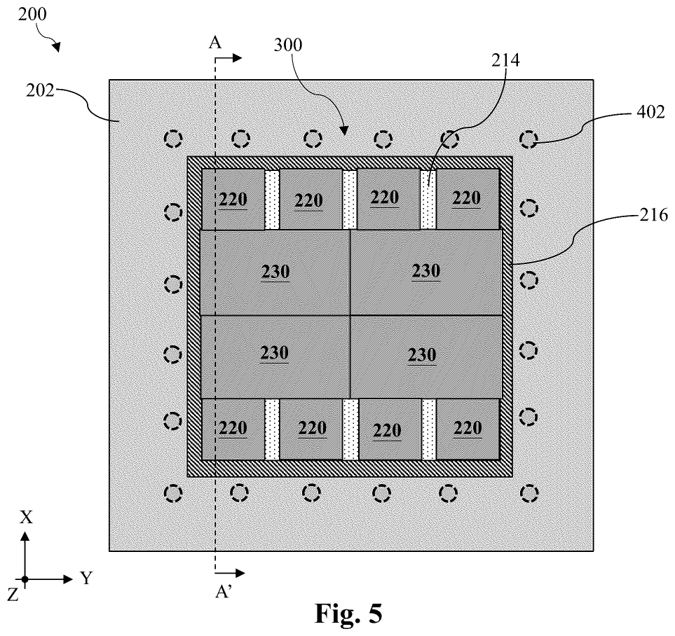

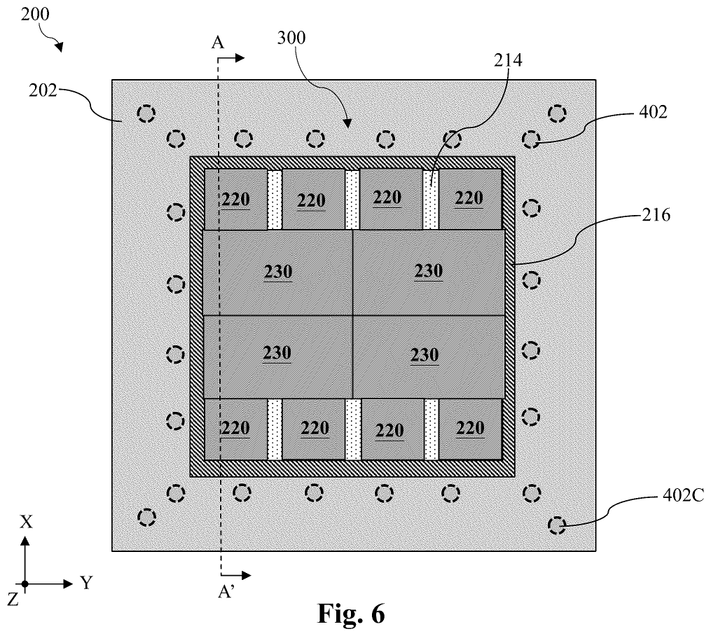

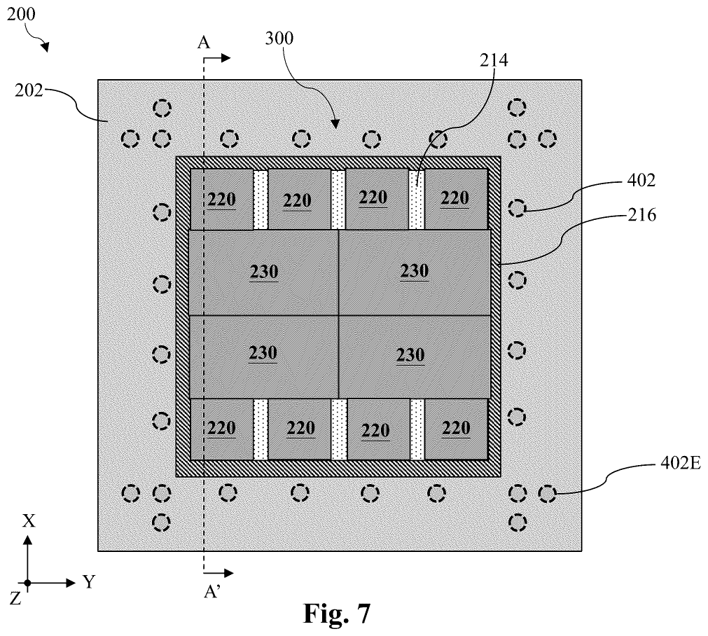

Reference is now made to FIGS. 5-7, which illustrate different pin hole patterns. In the embodiments representative in FIG. 5, a plurality of pin holes 402 are formed in the package substrate 202 to form a rectangular area that surrounds a perimeter of the package component 300. As shown in FIG. 5, the plurality of pin holes 402 are equally spaced apart from one another along both the X direction and the Y direction to go around the package component 300. In the embodiments represented in FIG. 6, as compared to the embodiments shown in FIG. 5, corner or diagonal pin holes 402C are additionally formed along the two diagonal lines of the rectangular shape of the package component 300. As shown in FIG. 6, the corner pin holes 402C are closer to an edge of the package substrate 202 to provide mechanical rigidity to the package substrate 202. In the embodiments represented in FIG. 7, as compared to the embodiments shown in FIG. 5, two edge extension pin holes 402E are additionally formed along each edge of the rectangle formed by the pin holes 402. As shown in FIG. 7, the edge extension pin holes 402E are closer to an edge of the package substrate 202 to provide mechanical rigidity to the package substrate 202. The pin hole pattern in FIG. 5 does not include any corner pin holes 402C shown in FIG. 6 or any edge extension pin holes 402E shown in FIG. 7. While the pin hole pattern in FIG. 5 may provide lower mechanical strength, the omission of corner pin holes 402C and edge extension pin holes 402E allow insertions of other components (such as passive components, capacitors, or resistors) or conductive features.

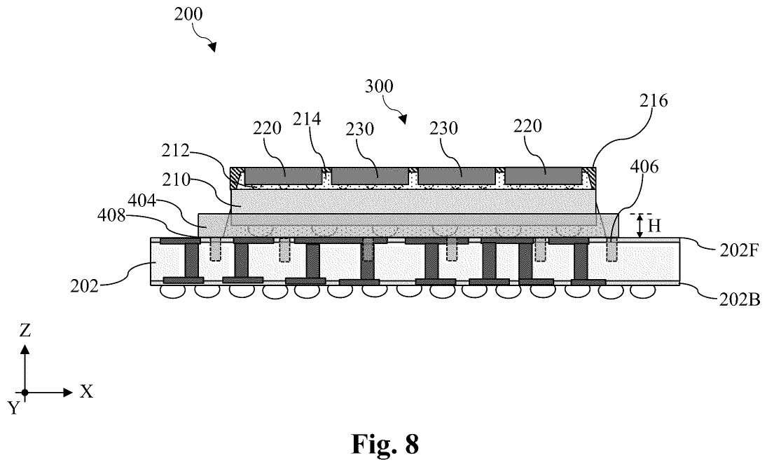

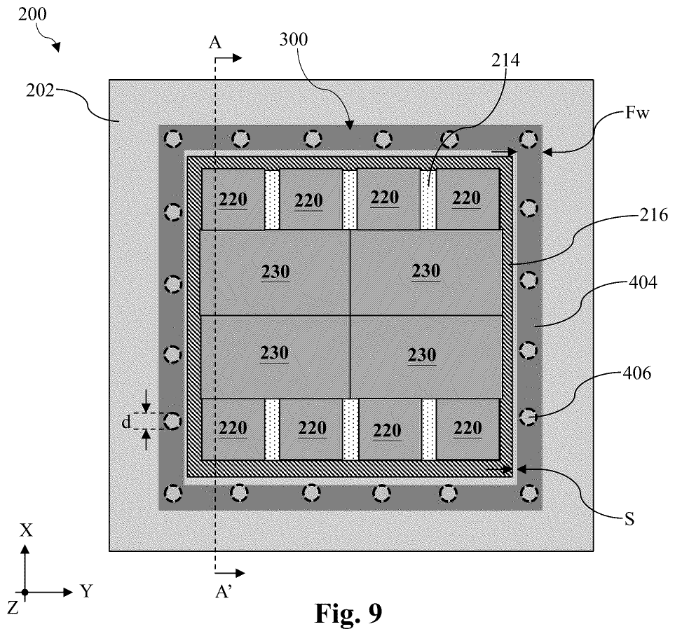

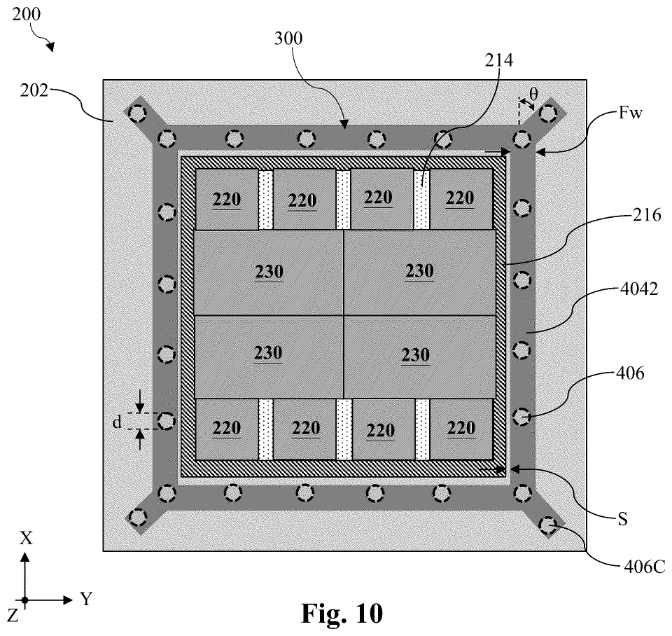

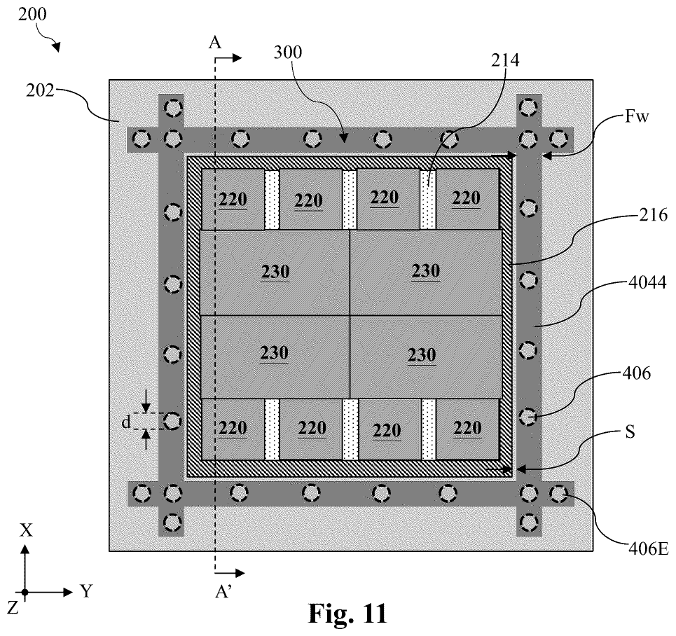

Referring to FIGS. 1 and 8-11, method 1000 includes a block 1006 where a metal frame 404 is installed on the package substrate 202 such that guide pins 406 on the metal frame 404 are inserted into the pin holes 402. The guide pins 406 are integral part of the metal frame 404 and extend from a bottom surface of the metal frame 404. In some embodiments, the metal frame 404 and the guide pins 406 are made of aluminum (Al), copper (Cu), iron (Fe), stainless steel, nickel (Ni), cobalt (Co), or an alloy thereof and may be fabricated using cast molding or 3-dimensional (3D) printing. At block 1006, the metal frame 404 is installed on the package substrate 202 in a way that each of the guide pins 406 is vertically aligned with and inserted into a pin hole 402. The insertion of the guide pins 406 into the pin holes 402 provide mechanical anchoring of the metal frame 404 to the package substrate 202. Because a coefficient of thermal expansion (CTE) of the metal frame 404 is smaller than a CTE of the package substrate 202, such mechanical anchoring allows the metal frame 404 to increase an effective CTE of the package substrate 202. That is, the metal frame 404 reduces the warpage of the package substrate 202 relative to the metal lid to be described below. As illustrated in FIGS. 8-11, the metal frame 404 may include different configurations to go along with different pin hole arrangements. Referring first to FIGS. 8 and 9, the metal frame 404 includes guide pins 406 that are equally spaced apart. When installing the metal frame 404 on the package substrate 202 in FIG. 9, each of the guide pins 406 are inserted into the pin holes 402. FIG. 10 illustrates a first reinforced metal frame 4042. The first reinforced metal frame 4042 includes not only the guide pins 406 but also corner guide pins 406C for insertion into the corner pin holes 402C shown in FIG. 6. FIG. 11 illustrates a second reinforced metal frame 4044. The second reinforced metal frame 4044 includes not only the guide pins 406 but also edge extension pins 406E for insertion into the edge extension pin holes 402E shown in FIG. 7. As shown in FIG. 8, with the guide pins 406 inserted in the pin holes 402, a bottom surface of the metal frame 404 lands on the top surface of the package substrate 202. As illustrated in FIGS. 9-11, the metal frame 404 or the reinforced variants 4042 and 4044 extends continuously around the package component 300. In some embodiments illustrated in FIG. 8, a height H of the metal frame 404 is such that a top surface of the metal frame 404 is higher than a bottom surface of the interposer 210 but lower than a top surface of a to-be-deposited thermal interface material (TIM) layer 410 (described below). It can be said that the metal frame 404 surrounds the interposer 210. In some embodiments represented in FIG. 8, an adhesive 408 may be applied at the interface between the metal frame 404 and the package substrate 202. In some instances, the adhesive 408 may include a die attach film (DAF) gel, silicone, polyimide (PI), or epoxy. When an adhesive is used, the adhesive 408 may come between sidewall of guide pins 406 and sidewalls of the pin holes 402.

Reference is once again made to FIGS. 9-11. As shown in FIG. 9, the metal frame 404 has a frame width Fw and is spaced apart from the package component 300 by a spacing S. Each of the guide pins 406 is cylindrical in shape and has a diameter d. In some embodiment, the frame width Fw is between about 0.03 and about 0.1 of the smaller one of the die width DW and the die length DL. The spacing S is about 0.05 and 0.1 of the frame width Fw. The diameter d of the guide pin 406 is between about 0.3 and 1 of the frame width Fw. Compared to the metal frame 404, the first reinforced metal frame 4042 in FIG. 10 additionally includes diagonal extensions that forms an angle θ with the X direction. The angle θ may be between 30° and about 60°, such as between 40° and about 50°. The relationships among the frame width Fw, diameter d, and spacing S hold true for the first reinforced metal frame 4042. Compared to the metal frame 404, the second reinforced metal frame 4044 in FIG. 11 additionally includes edge extensions that forms a zero-degree angle or a 90° angle with the X direction. The relationships among the frame width Fw, diameter d, and spacing S hold true for the second reinforced metal frame 4044.

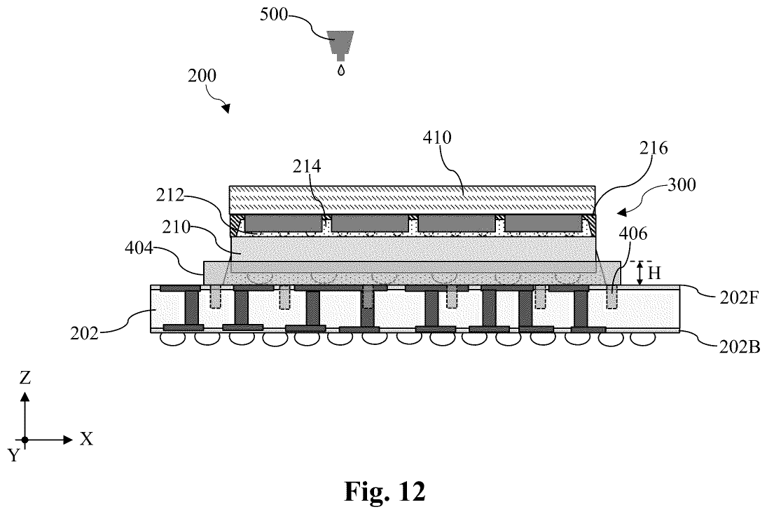

Referring to FIGS. 1 and 12, method 1000 includes a block 1008 where a thermal interface material (TIM) layer 410 is deposited over the package component 300. For purpose of the present disclosure, TIM refers to materials that are placed between an electronic device and a heat sink to improve heat dissipation of the electronic device. Because voids and gaps introduce air in the heat conduction path and air has low thermal conductivity, one of TIM's functions is to fill the gaps between the electronic device and the heat sink so as to reduce voids and gaps. To serve the gap filling function well, TIM or a precursor of TIM should possess reasonable flowability or flexibility. Additionally, TIM should have sufficient thermal conductivity to facilitate heat conduction. Furthermore, it is desirable that TIM has good stress absorption property to protect the electric device and prevent delamination. According to the present disclosure, at block 1008, the TIM layer 410 may be applied in a gel form or a liquid form. In some embodiments, the TIM layer 410 may include a gallium alloy, zinc oxide (ZnO), or aluminum nitride (AlN). As shown in FIG. 12, the TIM layer 410 is deposited over the package component 300 using a dispensing system having a dispensing head 500, including back sides of the HBM dies 220 and the SoC dies 230. In some embodiments, the TIM layer 410 is disposed on the molding compound 216. In some embodiments, the TIM layer 410 may have a thickness between about 25 μm and about 60 μm.

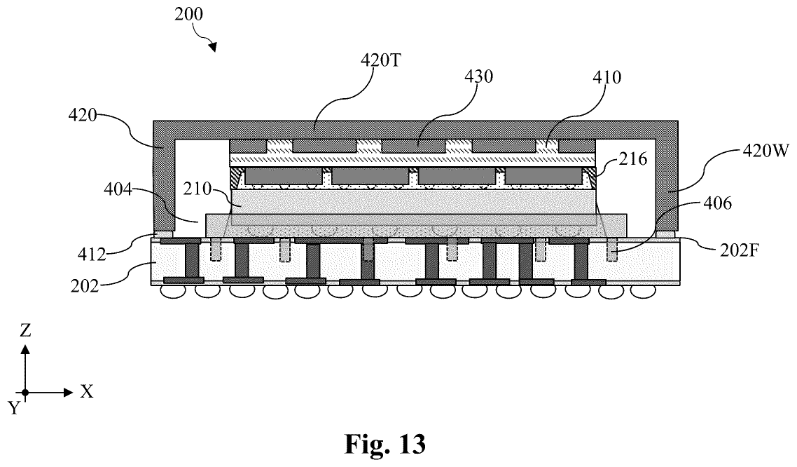

Referring to FIGS. 1 and 13, method 1000 includes a block 1010 where an adhesive 412 is dispensed over a top surface of the package substrate 202. As will be described below, method 1000 attaches a metal lid 420 to the package component 300 and the package substrate 202. The metal lid 420 engages the package component 300 by way of the TIM layer 410 and attaches to the top surface of the package substrate 202 through the adhesive 412. At block 1010, the adhesive 412 is selectively deposited over a landing area on the top surface of the package substrate 202. When the metal lid 420 is placed over the package substrate 202, a lower edge of a lid wall of the metal lid 420 is going to engage the adhesive 412 in the landing area. In some embodiments, the selective dispensing of the adhesive 412 may be performed using a dispensing system. The dispensing system includes a dispensing head that dispenses or injects the adhesive 412 in a gel form, a liquid form or a paste form. A stepper of the dispensing system may move the dispensing head precisely over the landing area. In some embodiments, the adhesive 412 may include a die attach film (DAF), silicone, polyimide (PI), or epoxy. Because the primary function of the adhesive 412 is adhesion, not heat dissipation/conduction, the adhesive 412 does not include highly thermally conductive materials such as beryllium oxide, aluminum oxide, zinc oxide, aluminum nitride, hexagonal boron nitride, metal (i.e., silver, copper, tin, or indium), diamond, graphene, carbon nanotubes, or graphite. The landing area surrounds the metal frame 404 and so does the adhesive 412.

Referring to FIGS. 1 and 13, method 1000 includes a block 1012 where a metal lid 420 is placed over the package component 300 and the package substrate 202 to engage the adhesive 412 and the TIM layer 410. In some embodiments, the metal lid 420 may be formed of a metal or an alloy, such as aluminum (Al), copper (Cu), iron (Fe), stainless steel, nickel (Ni), cobalt (Co), or an alloy thereof. Example alloys may include an aluminum-copper alloy, an iron-nickel alloy, or an iron-nickel-cobalt alloy. The metal lid 420 has at least three functions. First, it serves as a heat sink to dissipate heat from the package component 300 by way of the TIM layer 410. Second, it provides structural rigidity to the package substrate 202 to prevent or reduce warping. Third, it creates a sealed environment to protect the package component 300. Referring to FIG. 13, the metal lid 420 includes a lid top 420T and a lid wall 420W that extends downward from a bottom surface of the lid top 420T. At block 1012, the metal lid 420 is placed over the package component 300 and the package substrate 202 such that bottom edges of lid wall 420W engage the adhesive 412 on the package substrate 202 and the bottom surface of the lid top 420T presses on and engages the TIM layer 410 on the package component 300.

According to the present disclosure, the metal lid 420 also includes protruding patterns 430 that extend downward from the bottom surface of the lid top 420T. These protruding patterns 430 share the same composition with the metal lid 420. In some embodiments, the metal lid 420 and the protruding patterns 430 may be fabricated using cast molding or 3D printing. As shown in FIG. 13, when the metal lid 420 is installed over the package component 300 and the package substrate 202, the protruding patterns 430 extend into the TIM layer 410. The protruding patterns 430 form a heat spreader as a whole to spread or distribute heat from the TIM layer 410 to the metal lid 420. In some embodiments represented in FIG. 13, the protruding patterns 430 are fractured such that the TIM layer 410 may extend between neighboring protruding patterns 430 to contact the bottom surface of the lid top 420T. Because the protruding patterns 430 are to engage the TIM layer 410 to spread heat, an area of the protruding patterns 430 vertically overlap with an area of the TIM layer 410. In some embodiments, the protruding patterns 430 (i.e., the heat spreader) define a first rectangular area and the package component 300 defines a second rectangular area. When the metal lid 420 is installed over the package component 300 and the package substrate 202, the first rectangular area completely covers the second rectangular area. In some instances, the first rectangular area is about 5% to about 20% greater than the second rectangular area to ensure that the TIM layer 410 completely engage the protruding patterns 430.

The protruding patterns 430 may come in different configurations. FIGS. 15-19 illustrates a first configuration 430-1, a second configuration 430-2, a third configuration 430-3, a fourth configuration 430-4, and a fifth configuration 430-5. It should be understood that the first configuration 430-1, the second configuration 430-2, the third configuration 430-3, the fourth configuration 430-4, and the fifth configuration 430-5 are different implementations of the protruding patterns 430. Reference is first made to FIG. 15. The first configuration 430-1 includes an array of islet patterns 440 that are surrounded by corner patterns 450 and edge patterns 460. Each of the islet patterns 440 is rectangular in shape in a top view. Each of the corner patterns 450 has an L-shape in a top view. As a whole, the first configuration 430-1 has a width W along the X direction and a length L along the Y direction. To ensure full engagement with the TIM layer 410, the width W is greater than the die width DW and the length L is greater than the die length DL. In some instances, the width W is about 2.5% to about 10% greater than the die width DW and the length L is about 2.5% to about 10% greater than the die length DL. In some implementations, the islet patterns 440, corner patterns 450, edge patterns 460 are spaced apart along the X direction by gaps gx and along the Y direction by gaps gy. Each of the gaps gx is between 0.05 W and about 0.1 W and each of the gaps gy is between about 0.05 L and about 0.1 L. The first configuration 430-1 represents protruding patterns 430 that are uniformly fractured and distributed.

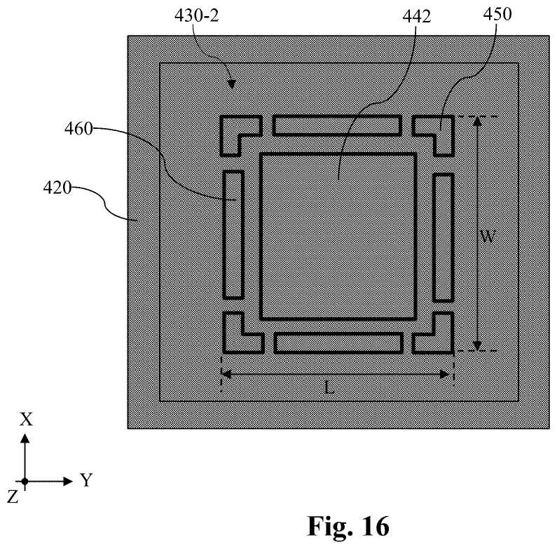

Reference is now made to FIG. 16. Instead of having the array of islet patterns 440 that are spaced apart from one another as in the first configuration 430-1 in FIG. 15, the second configuration 430-2 includes a bulk pattern 442. The bulk pattern 442 is surrounded by corner patterns 450 and edge patterns 460. The bulk pattern 442 is rectangular in shape in a top view. The bulk pattern 442 provides the metal lid 420 with a greater structural rigidity. As compared to the first configuration 430-1, the bulk pattern 442 in the second configuration 430-2 may reduce the flexibility of the metal lid 420. As a whole, the second configuration 430-2 has a width W along the X direction and a length L along the Y direction. To ensure full engagement with the TIM layer 410, the width W is greater than the die width DW and the length L is greater than the die length DL. In some instances, the width W is about 2.5% to about 10% greater than the die width DW and the length L is about 2.5% to about 10% greater than the die length DL.

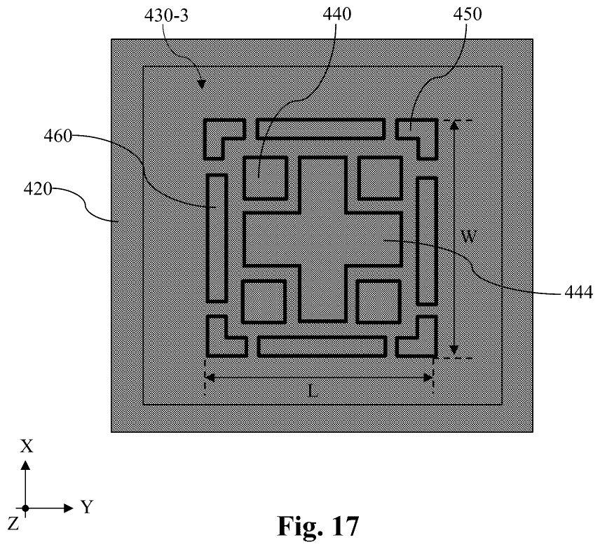

Reference is then made to FIG. 17. Instead of having the array of islet patterns 440 that are spaced apart from one another as in the first configuration 430-1 in FIG. 15, the third configuration 430-3 includes a cross pattern 444. In the depicted embodiments, the cross pattern 444 and four islet patterns 440 together form a rectangular area that is surrounded by corner patterns 450 and edge patterns 460. The cross pattern 444 provides the metal lid 420 with a greater structural rigidity along the X direction and the Y direction. As compared to the first configuration 430-1, the cross pattern 444 in the third configuration 430-3 may reduce the flexibility of the metal lid 420. As a whole, the third configuration 430-3 has a width W along the X direction and a length L along the Y direction. To ensure full engagement with the TIM layer 410, the width W is greater than the die width DW and the length L is greater than the die length DL. In some instances, the width W is about 2.5% to about 10% greater than the die width DW and the length L is about 2.5% to about 10% greater than the die length DL.

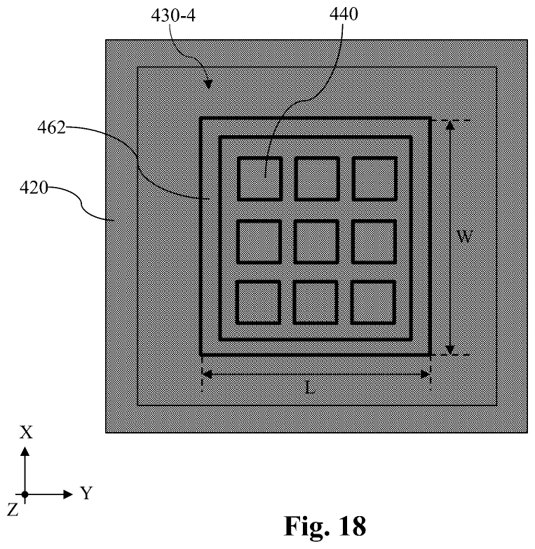

Reference is made to FIG. 18. Instead of including the fractured corner patterns 450 and edge patterns 460 as in the first configuration 430-1 in FIG. 15, the fourth configuration 430-4 includes a continuous perimeter pattern 462 that surrounds the islet patterns 440. The continuous perimeter pattern 462 forms a closed loop and may serve as a dam to confine the TIM layer 410 when the metal lid 420 is installed. The perimeter pattern 462 helps ensure that the fourth configuration 430-4 fully engages the TIM layer 410. As a whole, the fourth configuration 430-4 has a width W along the X direction and a length L along the Y direction. To ensure full engagement with the TIM layer 410, the width W is greater than the die width DW and the length L is greater than the die length DL. In some instances, the width W is about 2.5% to about 10% greater than the die width DW and the length L is about 2.5% to about 10% greater than the die length DL.

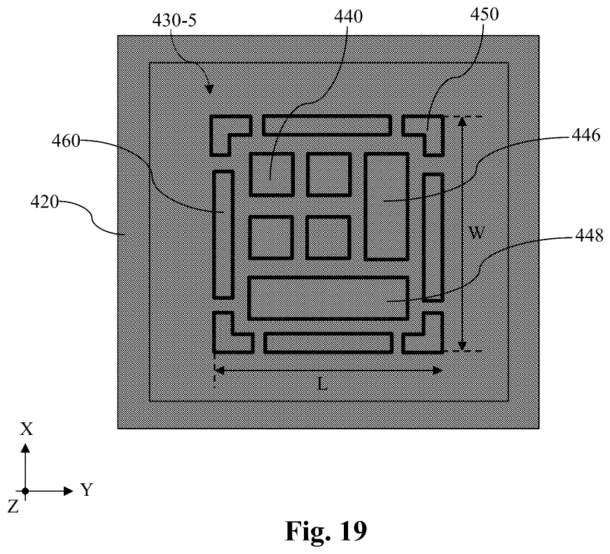

Reference is made to FIG. 19. Instead of including the fully fractured islet patterns 440 as in the first configuration 430-1 in FIG. 15, at least two of the islet patterns 440 in the fifth configuration 430-5 are merged to form larger island patterns. The island patterns are formed at locations such that when the metal lid 420 is installed, the island patterns vertically overlap local hot spots to help dissipate heat better. The island patterns and the remaining islet patterns 440 form a rectangular area that is surrounded by the fractured corner patterns 450 and edge patterns 460. In the depicted embodiments, the fifth configuration 430-5 includes a first island pattern 446 and a second island pattern 448. The first island pattern 446 is equivalent to two islet patterns 440 merged together. The second island pattern 448 is equivalent to three islet patterns 440 merged together. As a whole, the fifth configuration 430-5 has a width W along the X direction and a length L along the Y direction. To ensure full engagement with the TIM layer 410, the width W is greater than the die width DW and the length L is greater than the die length DL. In some instances, the width W is about 2.5% to about 10% greater than the die width DW and the length L is about 2.5% to about 10% greater than the die length DL.

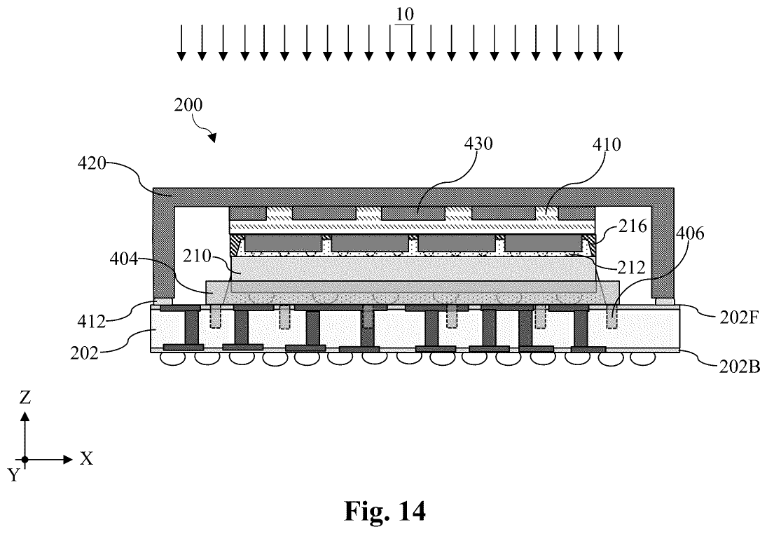

Referring to FIGS. 1 and 14, method 1000 includes a block 1014 where the adhesive 412 and the TIM layer 410 are cured. In some embodiments, the adhesive 412, the TIM layer 410, and the adhesive used to bond the metal frame 404 are thermally curable. In these embodiments, the WIP structure 200 shown in FIG. 14 may be subject to an anneal process 10 to cure the adhesive 412, the TIM layer 410, and the adhesive used to bond the metal frame 404. In some embodiments, the anneal process 10 may include a curing temperature between about 100° C. and about 200° C. and a curing time between about 1 hour and about 2 hours.

The present disclosure provides many embodiments. In one aspect, the present disclosure provides a package structure. The package structure includes a package substrate, a package component bonded to the package substrate and including a plurality of dies, a lid disposed over the package component and the package substrate, and a thermal interface material (TIM) layer sandwiched between the package component and the lid. The lid includes a plurality of heat spreader patterns that extend from a bottom surface of the lid into the TIM layer.

In some embodiments, the package component further includes an interposer bonded to the package substrate and the plurality of dies are bonded to the interposer. In some embodiments, the plurality of dies include a high-bandwidth-memory (HBM) die and a system-on-chip (SoC) die. In some embodiments, the package component includes a first rectangular area, the plurality of heat spreader patterns define a second rectangular area, and the second rectangular area vertically overlaps the first rectangular area. In some embodiments, the lid and the plurality of heat spreader patterns include aluminum (Al), copper (Cu), iron (Fe), stainless steel, nickel (Ni), cobalt (Co), or an alloy thereof. In some instances, the TIM layer includes a gallium alloy, aluminum nitride, or zinc oxide. In some implementations, the package structure further includes a metal frame disposed over the package substrate and extending continuously around the package component. In some instances, the metal frame includes a plurality of guide pins that extend into the package substrate. In some embodiments, the metal frame is covered by the lid. In some embodiments, the metal frame includes aluminum (Al), copper (Cu), iron (Fe), stainless steel, nickel (Ni), cobalt (Co), or an alloy thereof.

In another aspect, the present disclosure provides a package structure. The package structure includes a package substrate, a package component that includes an interposer bonded to a top surface of the package substrate, and a plurality of dies bonded to a top surface of the interposer, a metal frame disposed on the package substrate and surrounding the interposer, a thermal interface material (TIM) layer disposed on the package component, and a lid disposed over the package component, the metal frame and the package substrate.

In some embodiments, the lid includes a lid top, and a lid wall extending downward along a perimeter of the lid top. A bottom surface of the lid top interfaces the TIM layer and the lid wall surrounds the package component, the metal frame, and the TIM layer. In some embodiments, a bottom surface of the lid wall engages the package substrate by way of an adhesive. In some embodiments, the metal frame includes a plurality of guide pins that extend into the package substrate. In some embodiments, the lid includes a plurality of heat spreader patterns that extend from a bottom surface of the lid into the TIM layer. In some implementations, the lid and the plurality of heat spreader patterns include aluminum (Al), copper (Cu), iron (Fe), nickel (Ni), cobalt (Co), or an alloy thereof.

In still another aspect, the present disclosure provides a package structure. The package structure includes a package substrate, a package component bonded to the package substrate and including a plurality of dies, a metal frame disposed on the package substrate and surrounding the package component, a lid disposed over the package component, the package substrate, and the metal frame, and a thermal interface material (TIM) layer sandwiched between the package component and the lid. The lid includes a plurality of heat spreader patterns that extend from a bottom surface of the lid into the TIM layer.

In some embodiments, the metal frame includes a plurality of guide pins that extend into the package substrate. In some embodiments, the package substrate includes a plurality of contact features, and the plurality of guide pins are insulated from the plurality of contact features. In some implementations, the TIM layer includes a gallium alloy, aluminum nitride, or zinc oxide.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a package component bonded to the package substrate and comprising a plurality of dies;
a lid disposed over the package component and the package substrate; and
a thermal interface material (TIM) layer sandwiched between the package component and the lid,
wherein the lid comprises a plurality of heat spreader patterns that extend from a bottom surface of the lid into the TIM layer.

2. The package structure of claim 1,
wherein the package component further comprises an interposer bonded to the package substrate,
wherein the plurality of dies are bonded to the interposer.

3. The package structure of claim 1, wherein the plurality of dies comprise a high-bandwidth-memory (HBM) die and a system-on-chip (SoC) die.

4. The package structure of claim 1,
wherein the package component comprises a first rectangular area,
wherein the plurality of heat spreader patterns define a second rectangular area,
wherein the second rectangular area vertically overlaps the first rectangular area.

5. The package structure of claim 1, wherein the lid and the plurality of heat spreader patterns comprise aluminum (Al), copper (Cu), iron (Fe), stainless steel, nickel (Ni), cobalt (Co), or an alloy thereof.

6. The package structure of claim 1, wherein the TIM layer comprises a gallium alloy, aluminum nitride, or zinc oxide.

7. The package structure of claim 1, further comprising:
a metal frame disposed over the package substrate and extending continuously around the package component.

8. The package structure of claim 7, wherein the metal frame comprises a plurality of guide pins that extend into the package substrate.

9. The package structure of claim 7, wherein the metal frame is covered by the lid.

10. The package structure of claim 7, wherein the metal frame comprises aluminum (Al), copper (Cu), iron (Fe), stainless steel, nickel (Ni), cobalt (Co), or an alloy thereof.

11. A package structure, comprising:
a package substrate;
a package component comprising:
an interposer bonded to a top surface of the package substrate, and
a plurality of dies bonded to a top surface of the interposer;
a metal frame disposed on the package substrate and surrounding the interposer;
a thermal interface material (TIM) layer disposed on the package component; and
a lid disposed over the package component, the metal frame and the package substrate.

12. The package structure of claim 11,
wherein the lid comprises:
a lid top, and
a lid wall extending downward along a perimeter of the lid top,
wherein a bottom surface of the lid top interfaces the TIM layer,
wherein the lid wall surrounds the package component, the metal frame, and the TIM layer.

13. The package structure of claim 12, wherein a bottom surface of the lid wall engages the package substrate by way of an adhesive.

14. The package structure of claim 11, wherein the metal frame comprises a plurality of guide pins that extend into the package substrate.

15. The package structure of claim 11, wherein the lid comprises a plurality of heat spreader patterns that extend from a bottom surface of the lid into the TIM layer.

16. The package structure of claim 15, wherein the lid and the plurality of heat spreader patterns comprise aluminum (Al), copper (Cu), iron (Fe), nickel (Ni), cobalt (Co), or an alloy thereof.

17. A package structure, comprising:
a package substrate;
a package component bonded to the package substrate and comprising a plurality of dies;
a metal frame disposed on the package substrate and surrounding the package component;
a lid disposed over the package component, the package substrate, and the metal frame; and
a thermal interface material (TIM) layer sandwiched between the package component and the lid,
wherein the lid comprises a plurality of heat spreader patterns that extend from a bottom surface of the lid into the TIM layer.

18. The package structure of claim 17, wherein the metal frame comprises a plurality of guide pins that extend into the package substrate.

19. The package structure of claim 18,
wherein the package substrate comprises a plurality of contact features, and
wherein the plurality of guide pins are insulated from the plurality of contact features.

20. The package structure of claim 17, wherein the TIM layer comprises a gallium alloy, aluminum nitride, or zinc oxide.
